(19) United States
(12) Patent Application Publication
(10) Pub. No.: US 2025/0105532 A1
(43) Pub. Date: Mar. 27, 2025

(54) TERMINAL BLOCK MONITORING DEVICE

(71) Applicant: DSEN CO., LTD., Gyeonggi-do (KR)

(72) Inventor: Jong Pil JI, Seoul (KR)

(21) Appl. No.: 18/724,951

(22) PCT Filed: Dec. 20, 2022
(86) PCT No.: PCT/KR2022/020825

§ 371 Date: Jun. 27, 2024

(30) Foreign Application Priority Data
May 10, 2022 (KR) 10-2022-0057090

(51) Int. Cl. H01R 9/24; G01B 13/12; G01K 1/024; G01R 19/00; G08B 21/22; G08B 25/00

(52) U.S. Cl. CPC H01R 9/2425; G01B 13/12; G01K 1/024; G01R 19/0092; G08B 21/22; G08B 25/00

(57) ABSTRACT

The present invention comprises: a current detection unit (12) provided in a terminal block (10) connecting a wire (20), so as to detect a current flowing through the wire (20); a temperature detection unit (14) provided in the terminal block (10) so as to detect the temperature of the terminal block (10); a tube (50) made of an elastic material so as to be provided horizontally on the ground in front of the terminal block (10); a first pressure sensor and transmitter module (52) provided at one end of the tube (50) so as to detect a change in pressure when a specific part of the tube (50) is stepped on and pressed by an approaching person, and thus transmits a first pressure detection signal; a second pressure sensor and transmitter module (54) provided at the other end of the tube (50) so as to detect a change in pressure when a specific part of the tube (50) is stepped on and pressed by an approaching person, and thus transmits a second pressure detection signal; a reception unit (60) for receiving the first and second pressure detection signals; and a monitoring control unit (16) provided in the terminal block (10) so as to receive a current detection value provided from the current detection unit (12), a temperature detection value provided from the temperature detection unit (14), and the first and second pressure detection signals provided from the reception unit (60) and provide same to a central management center (40) through an information communication network (30), and thus the central management center (40) monitors the terminal block (10) with respect to current and temperature and monitors a person approaching the terminal block (10).

### TECHNICAL FIELD

The present invention relates to a terminal block monitoring device.

### BACKGROUND ART

A terminal block is used to facilitate the connection of wires, and a plurality of terminal blocks are arranged on a terminal board.

Since the terminal block is a part for connecting an end of an electric wire to an end of another electric wire, the electric wires may be incompletely connected at the terminal block. An overheating may occur due to a current at the above incompletely connected part, and an accident such as fire may occur due to the overheating. It is also necessary to monitor unauthorized access by a person to the terminal block.

Thus, it is necessary that information obtained by detecting a current and a temperature of the terminal block and information about whether a person approaches the terminal block are provided to a central management center, and the central management center monitors the terminal block with respect to the current, temperature, and human access, to prevent accidents caused by overcurrent and overheating that may occur in the terminal block, and to monitor human access to ensure that the terminal block can be used safely against accidents caused by overcurrent, overheating, and unauthorized human access to the terminal block.

Related art document information: Korean Unexamined Patent Publication No. 10-2020-0120212 (published on Oct. 21, 2020) titled by “TERMINAL BLOCK TEMPERATURE MONITORING SYSTEM”

The “terminal block temperature monitoring system” according to the above related art document may consistently monitor a terminal block and recognize in advance whether overheating of the terminal block proceeds.

However, the “terminal block temperature monitoring system” of Korean Unexamined Patent Publication No. 10-2020-0120212 may consistently monitor the terminal block and recognize in advance whether overheating of the terminal block proceeds, but cannot provide a central management center with information obtained by detecting a current and a temperature of the terminal block and information about whether a person approaches the terminal block, and allow the central management center to monitor the terminal block with respect to the current, temperature, and human access, and thus accidents caused by overcurrent and overheating, which may occur in the terminal block, cannot be prevented.

### DISCLOSURE

### Technical Problem

In order to solve the above-described problem, an object of the present invention is to provide a terminal block monitoring device in which information obtained by detecting a current and a temperature of the terminal block and information about whether a person approaches the terminal block are provided to a central management center, the central management center monitors the terminal block with respect to the current, temperature, and human access, to prevent accidents caused by overcurrent and overheating that may occur in the terminal block, and to monitor human approach.

### Technical Solution

According to one aspect of the present invention in order to achieve the above-mentioned object, the terminal block monitoring device includes:
a current detection unit (12) provided in a terminal block (10) connecting a wire (20), so as to detect a current flowing through the wire (20);
a temperature detection unit (14) provided in the terminal block (10) so as to detect a temperature of the terminal block (10);
a tube (50) made of an elastic material so as to be provided horizontally on a ground in front of the terminal block (10);
a first pressure sensor and transmitter module (52) provided at one end of the tube (50) so as to detect a change in pressure when a specific part of the tube (50) is stepped on and pressed by an approaching person, and thus transmit a first pressure detection signal;
a second pressure sensor and transmitter module (54) provided at an opposite end of the tube (50) so as to detect a change in pressure when a specific part of the tube (50) is stepped on and pressed by an approaching person, and thus transmit a second pressure detection signal;
a reception unit (60) for receiving the first and second pressure detection signals; and
a monitoring control unit (16) provided in the terminal block (10) so as to receive a current detection value provided from the current detection unit (12), a temperature detection value provided from the temperature detection unit (14), and the first and second pressure detection signals provided from the reception unit (60) and provide the received values to a central management center (40) through an information communication network (30), and thus the central management center (40) monitors the terminal block (10) with respect to current and temperature and monitors a person approaching the terminal block (10).

The terminal block monitoring device further includes:
a pressing location determination unit (70) that receives the first and second pressure detection signals provided from the reception unit (60), determines a pressing location (56) of the tube (50) based on times of receiving the first and second pressure detection signals, a difference between the times of receiving the first and second pressure detection signals, a length of the tube (50), and a pressure change transfer rate subject to a specific part pressed inside the tube (50), provides the pressing location to the monitoring control unit (16), and allows the monitoring control unit (16) to provide the pressing location (56) to the central management center (40), so that the central management center (40) monitors a location of a person approaching the terminal block (10).

### Advantageous Effects

According to the present invention, information obtained by detecting a current and a temperature of the terminal block (10) and information about whether a person approaches the terminal block (10) are provided to the central management center (40), and the central management center (40) monitors the terminal block (10) with respect to the current, temperature, and human access to prevent accidents caused by overcurrent and overheating, which may occur in the terminal block (10), so that the terminal block (10) can be used safely against accidents caused by the overcurrent, overheating, and unauthorized human access to the terminal block (10).

### DESCRIPTION OF DRAWINGS

FIG. 1 is a diagram showing one embodiment of a terminal block applied to a terminal block monitoring device according to the present invention.

FIG. 2 is a diagram showing one embodiment of the terminal block monitoring device according to the present invention.

### BEST MODE

### Mode for Invention

Hereinafter, the embodiments of the present invention will be described in detail with reference to the accompanying drawings.

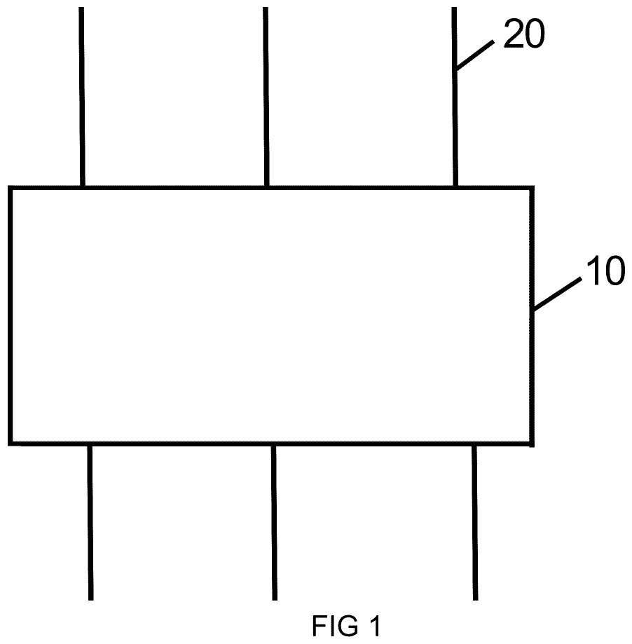

FIG. 1 is a diagram showing one embodiment of a terminal block applied to a terminal block monitoring device according to the present invention, and composed on a terminal block 10 and a wire 20.

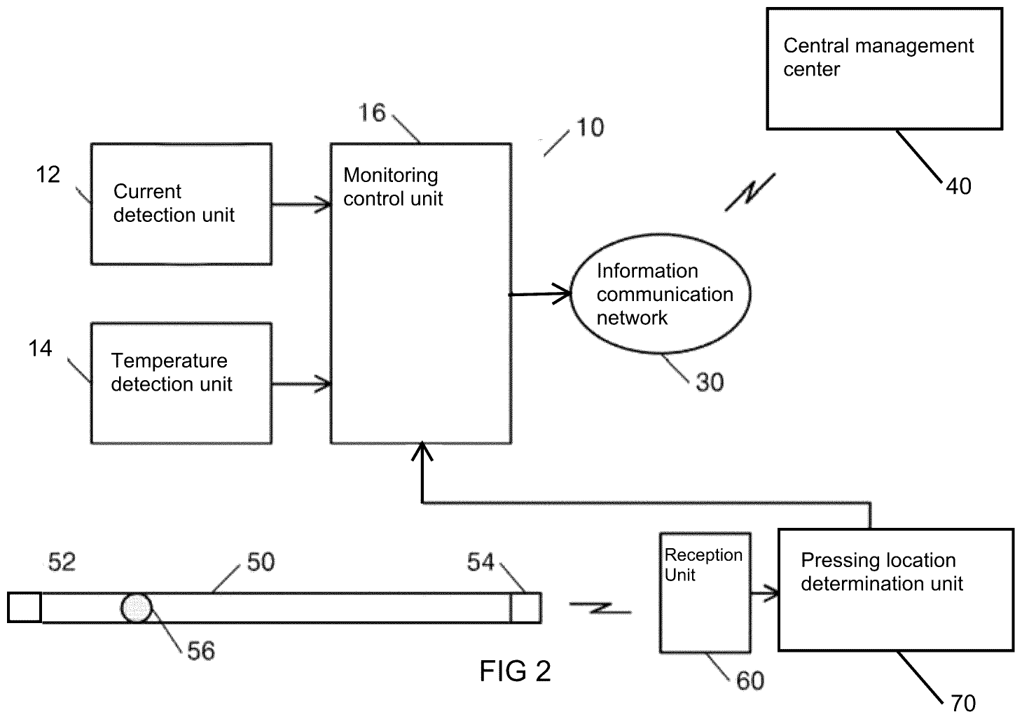

FIG. 2 is a diagram showing one embodiment of the terminal block monitoring device according to the present invention, and includes a terminal block 10, an information communication network 30, a central management center 40, a tube 50, first and second pressure sensor and transmitter modules 52 and 54, a pressing location 56, a reception unit 60, and a pressing location determining unit 70. The terminal block 10 includes a current detection unit 12, a temperature detection unit 14, and a monitoring control unit 16.

In FIGS. 1 to 2, the current detection unit 12 is installed in the terminal block 10 connecting the wire 20 to detect a current flowing in the wire 20, thereby providing a current detection value to the monitoring control unit 16.

The temperature detection unit 14 is installed in the terminal block 10 to detect a temperature of the terminal block 10, thereby providing a temperature detection value to the monitoring control unit 16.

The tube 50 is formed of an elastic material so as to be installed horizontally on a ground in front of the terminal block 10. It is preferable to use rubber as the elastic material.

The first pressure sensor and transmitter module 52 is installed at one end of the tube 50 to detect a change in pressure when a specific part of the tube 50 is stepped on and pressed by an approaching person, and thus transmit a first pressure detection signal.

The second pressure sensor and transmitter module 54 is installed at the other end of the tube 50 to detect a change in pressure when a specific part of the tube 50 is stepped on and pressed by an approaching person, and thus transmit a second pressure detection signal.

One of the two first and second pressure sensor and transmitter modules 52 and 54 may be selected and implemented, however, it is preferable to use the both to more stably detect changes in pressure.

The reception unit 60 receives the first and second pressure detection signals by wire or wirelessly and provides the received first and second pressure detection signals to the monitoring control unit 16.

The monitoring control unit 16 is installed in the terminal block 10 to receive the current detection value provided from the current detection unit 12, the temperature detection value provided from the temperature detection unit 14, and the first and second pressure detection signals provided from the reception, so as to provide the received values and signals to the central management center 40 through the information communication network 30, so that the central management center 40 monitors the terminal block 10 with respect to the current and the temperature and monitors human access to the terminal block 10.

Additionally, the pressing location determination unit 70 receives the first and second pressure detection signals provided from the reception unit 60, determines a pressing location 56 of the tube 50 based on times of receiving the first and second pressure detection signals, a difference between the times of receiving the first and second pressure detection signals, a length of the tube 50, and a pressure change transfer rate subject to a specific part pressed inside the tube 50, provides the pressing location to the monitoring control unit 16, and allows the monitoring control unit 16 to provide the pressing location 56 to the central management center 40, so that the central management center 40 monitors a location of a person approaching the terminal block 10.

According to the present invention as described above, information obtained by detecting a current and a temperature of the terminal block 10 and information about whether a person approaches the terminal block 10 are provided to the central management center 40, and the central management center 40 monitors the terminal block 10 with respect to the current, temperature, and human access, to prevent accidents caused by overcurrent and overheating, which may occur in the terminal block 10, so that the terminal block 10 can be used safely against accidents caused by the overcurrent, overheating, and unauthorized human access to the terminal block 10.

Although the technical idea of the present invention has been described above along with the accompanying drawings, the above description is provided merely as an exemplary embodiment of the present invention, and does not limit the present invention. Further, it will be apparent that a person having ordinary skill in the art may carry out various deformations and modifications within the scope of the technical idea of the present invention.

1. A terminal block monitoring device comprising:
a current detection unit (12) provided in a terminal block (10) connecting a wire (20), so as to detect a current flowing through the wire (20);
a temperature detection unit (14) provided in the terminal block (10) so as to detect a temperature of the terminal block (10);
a tube (50) made of an elastic material so as to be provided horizontally on a ground in front of the terminal block (10);
a first pressure sensor and transmitter module (52) provided at one end of the tube (50) so as to detect a change in pressure when a specific part of the tube (50) is stepped on and pressed by an approaching person, and thus transmit a first pressure detection signal;
a second pressure sensor and transmitter module (54) provided at an opposite end of the tube (50) so as to detect a change in pressure when a specific part of the tube (50) is stepped on and pressed by an approaching person, and thus transmit a second pressure detection signal;
a reception unit (60) for receiving the first and second pressure detection signals; and
a monitoring control unit (16) provided in the terminal block (10) so as to receive a current detection value provided from the current detection unit (12), a temperature detection value provided from the temperature detection unit (14), and the first and second pressure detection signals provided from the reception unit (60) and provide the received values to a central management center (40) through an information communication network (30), and thus the central management center (40) monitors the terminal block (10) with respect to current and temperature and monitors a person approaching the terminal block (10), and
further comprising:
a pressing location determination unit (70) that receives the first and second pressure detection signals provided from the reception unit (60), determines a pressing location (56) of the tube (50) based on times of receiving the first and second pressure detection signals, a difference between the times of receiving the first and second pressure detection signals, a length of the tube (50), and a pressure change transfer rate subject to a specific part pressed inside the tube (50), provides the pressing location to the monitoring control unit (16), and allows the monitoring control unit (16) to provide the pressing location (56) to the central management center (40), so that the central management center (40) monitors a location of a person approaching the terminal block (10).
